(19) United States
(12) Patent Application Publication
(10) Pub. No.: US 2010/0270558 A1
(43) Pub. Date: Oct. 28, 2010

(54) FABRICATING METHOD OF POLYCRYSTALLINE SILICON THIN FILM, POLYCRYSTALLINE SILICON THIN FILM FABRICATED USING THE SAME

(75) Inventors: Jae-Sang Ro, Seoul (KR); Won-Eui Hong, Seoul (KR)

Correspondence Address: CANTOR COLBURN, LLP, 20 Church Street, 22nd Floor, Hartford, CT, 06103, US

(73) Assignee: ENSILTECH CORPORATION, Seoul (KR)

(21) Appl. No.: 12/743,735

(22) PCT Filed: Nov. 21, 2008
(86) PCT No.: PCT/KR08/06863

§ 371 Date: May 19, 2010

(30) Foreign Application Priority Data
Nov. 21, 2007 (KR) 10-2007-0119234

(51) Int. Cl. H01L 29/786; H01L 21/336

(52) U.S. Cl. 257/66; 438/158; 257/E29.294; 257/E21.414

(57) ABSTRACT

Provided are a method of fabricating a polycrystalline silicon thin film using high temperature heat generated by Joule heating induced by application of an electrical field to a conductive layer, which can ensure process stability at high temperature and thus processing time can be reduced and a polycrystalline silicon thin film having excellent crystallinity can be obtained, a polycrystalline thin film using the method and a thin film transistor including the polycrystalline thin film. The method includes providing a substrate, forming a metal or metal alloy layer having a melting point of 13000 C or more on the substrate, forming an insulating layer on the metal or metal alloy layer, forming an amorphous silicon (a-Si) thin film, an amorphous/polycrystalline composite silicon thin film, or a poly-Si thin film on the insulating layer, and applying an electrical filed to the metal or metal alloy layer to induce Joule heating and generate high temperature heat, and crystallizing and annealing the amorphous silicon (a-Si) thin film, the amorphous/polycrystalline composite silicon thin film, or the poly-Si thin film using the high temperature heat.

### TECHNICAL FIELD

The present invention relates to a method of fabricating a polycrystalline silicon thin film, a polycrystalline thin film fabricated using the method, and a thin film transistor including the polycrystalline silicon thin film. More particularly, the present invention relates to a method of fabricating a polycrystalline silicon thin film using Joule heat generated by applying an electrical field to a conductive layer, the method using a metal or metal alloy layer having a melting point of 1300° C. or more as the conductive layer to ensure process stability at high temperature, thereby reducing processing time and obtaining a polycrystalline silicon thin film having excellent crystallinity, a polycrystalline silicon thin film fabricated by the method, and a thin film transistor (TFT) including the polycrystalline silicon thin film.

### BACKGROUND ART

Generally, amorphous silicon (a-Si) has disadvantages including low mobility of electrons functioning as charge carriers and a low aperture ratio, and other that makes it inappropriate for a CMOS process. However, a polycrystalline silicon (poly-Si) thin film device enables a driving circuit required for writing an image signal in a pixel to be mounted on a substrate in the same manner as a pixel TFT-array, implementation of which was impossible with an a-Si TFT. Accordingly, the poly-Si TFT device does not need to make a connection between several terminals and a driver IC, and thus it enables producibility and reliability to be increased and a thickness of a panel to be reduced. The poly-Si TFT device can also be fabricated using a fine processing technique of silicon LSI, and thus a fine interconnection can be formed. For this reason, there is no pitch limit occurring when a TAB is mounted on the driver IC, which is shown in the a-Si TFT, and reduction of a pixel and multi-pixels in a narrow viewing angle can be achieved. Unlike the TFT using a-Si, the TFT using poly-Si for an active layer has high switch capability and determines a channel location in the active layer by self-aligning, and thus miniaturization of the device and implementation of a CMOS device can be achieved. For these reasons, the poly-Si TFT has attracted attention as a critical device for implementation of a large display and practical use of a chip-on-glass (COG) product having a driver inside as a pixel switch device for an active-matrix flat panel display (e.g., a liquid crystal display (LCD) device or an organic light emitting diode (OLED) display device).

The poly-Si TFT may be fabricated in processes performed at both high and low temperature. For high temperature processes, a substrate has to be formed of an expensive material such as quartz, and thus is not appropriate for a large display. Accordingly, research on crystallizing an a-Si thin film into a poly-Si thin film at low temperature in a large scale has been actively conducted.

Low temperature techniques for forming poly-Si include solid phase crystallization (SPC), metal induced crystallization (MIC), metal induced lateral crystallization (MILC) and excimer laser crystallization (ELC).

SPC enables a uniform crystal quality to be obtained using inexpensive equipment, but requires high crystallization temperature and long processing time, and thus, for example, a glass substrate having a relatively low heat deflection temperature cannot be used, and productivity is low. In SPC, an a-Si thin film has to be annealed generally at 600 to 700° C. for about 1 to 24 hours to be crystallized into a poly-Si thin film. Moreover, in SPC, twin-growth is observed during solid state phase transformation from an amorphous phase to a crystal phase, and thus contains many crystal lattice defects in formed grains. These factors reduce electron and hole mobilities and increase a threshold voltage in the fabricated poly-Si TFT.

MIC has an advantage in that crystallization is accomplished at much lower temperature than the crystallization using SPC as a-Si is in contact with a specific metal. Metals for MIC include Ni, Pd, Ti, Al, Ag, Au, Co, Cu, Fe and Mn, which stimulate low temperature crystallization by forming a eutectic phase or silicide phase in response to a reaction with a-Si. However, in an actual process of fabricating a poly-Si TFT using MIC, these metals can cause serious contamination in a channel.

MILC is an application of MIC to induce lateral crystallization to a channel after a gate electrode is formed instead of depositing metal on a channel, and depositing thin metal on a source and a drain in a self-aligned structure to induce metal induced crystallization. Common metals for MILC include Ni and Pd. Poly-Si formed by MILC, compared to SPC, has better crystallinity and high field effect mobility, but it is known to exhibit a high leakage current characteristic. That is, it reduces metal contamination when compared to MIC, but does not completely overcome this problem. Meanwhile, as a technique improving upon MILC, there is a method known as field aided lateral crystallization (FALC). FALC has a fast crystallization rate and anisotropy in crystallization direction when compared to MILC, but still does not overcome metal contamination.

MIC, MILC and FALC are all effective for a decrease in crystallization temperature compared to SPC, but all have common disadvantages of long crystallization time and crystallization induced by metal. Thus, none of these techniques is free from metal contamination. Meanwhile, recently developed ELC makes prevention of such metal contamination and fabrication of a poly-Si thin film in a low temperature process on a glass substrate. Since a-Si deposited by low pressure chemical vapor deposition (LPCVD) or plasma enhanced chemical vapor deposition (PECVD) has a very high absorption coefficient for an ultraviolet region (λ=308 nm) which is a wavelength of excimer laser, an a-Si thin film can easily melt at an appropriate energy density. In crystallization of an a-Si thin film by excimer laser, both melting and solidification are accomplished within a very short period of time. For this reason, strictly speaking, ELC is not a low temperature process. However, since an ELC process undergoes crystallization due to melting and solidification very speedily progressing in a local melting region greatly affected by excimer laser, it may form poly-Si in an extremely short period of time (in a unit of several tens of ns) without damage to a substrate. That is, when laser is applied to a-Si of a structure including a glass substrate, an insulating layer and an a-Si thin film in a very short period of time, only the a-Si thin film is selectively annealed and thus is crystallized without damage to the underlying glass substrate. In addition, poly-Si formed in phase transformation from a liquid state to a solid state, compared to poly-Si formed by solid phase crystallization, has a thermodynamically stable grain structure and significantly reduces crystal defects in grains. Thus, the poly-Si formed by ELC has better characteristics than those formed by other crystallization techniques.

Nevertheless, ELC has several critical disadvantages. For example, these are problems of a laser system having non-uniform radiation amount of a laser beam, a laser process having an ultimately limited process region of a laser energy density for obtaining large grains, and a shot trace on a large display. The first two problems cause non-uniformity in grain size of the poly-Si thin film constituting an active layer of the poly-Si TFT. In addition, poly-Si produced along with phase transformation from a liquid state to a solid state undergoes volume expansion, and thus a severe protrusion phenomenon occurs to a surface from a place where a grain boundary is formed. This phenomenon directly affects a gate insulating layer formed in a subsequent process, and thus reduces a breakdown voltage due to non-uniform planarization ratio at an interface between the poly-Si and the gate insulating layer and device reliability such as hot carrier stress.

While sequential lateral solidification (SLS) has been developed in recent times to solve the instability of ELC described above, thereby succeeding in stabilizing the process region of the laser energy density, it still does not overcome the problems of the shot trace and the protrusion phenomenon to the surface. In view of the current trend of rapidly development of the flat panel display industry, technology for applying laser to a crystallization process for a substrate larger than 1 m×1 m, which is expected to be demanded for mass-production sooner or later, still has problems. Moreover, equipment for ELC and SLS is very expensive, and thus high initial investment and maintenance are required.

Accordingly, there is a need for a crystallization technique for an a-Si thin film which not only overcomes disadvantages of the laser crystallization such as the non-uniformity in irradiation amount according to a local process, the process limitation and the expensive equipment but also has advantages such as the speedy process without the damage to an underlying substrate, and production of high quality grains with almost no defects by high temperature phase transformation. Particularly, since an active matrix organic light emitting diode attracting much attention in the application to the next generation flat panel display in recent times adopts a current drive type compared to a voltage drive type of a TFT-LCD, the uniformity in grain size is a very important factor for a large substrate. Thus, the low temperature crystallization by ELC or SLS faces limits in the current flat panel display industries. Considering this reality, there is an eager demand for new technology to fabricate a high quality poly-Si thin film by low temperature crystallization without use of laser.

To solve these conventional problems, the inventors of the present invention have first suggested a crystallization method in Korean Patent Application No. 2004-37952, in which a Si thin film is preheated in a temperature range that does not deform the substrate in a process to create an intrinsic carrier therein, thereby lowering a resistance value to that capable of Joule heating, and an electrical field is directly applied to the preheated silicon thin film to perform Joule heating due to transfer of a carrier. This method is very innovative, so it can fabricate a high quality poly-Si thin film in a very short period of time at relatively low temperature.

The inventors of the present invention has also suggested, in Korean Patent Application No. 2005-73076, a crystallization method in which an ITO layer a conductive layer- and an insulating layer are formed on an insulating layer on a transparent substrate, and then a Si thin film is formed, thereby preventing damage of the Si thin film due to high heat generated by Joule heating induced by applying an electrical field to the ITO layer, and thus exhibiting improved performance in a very short period of time at a lower temperature than the conventional art, preferably, at room temperature, dopant activation and thermal oxide layer processes, and a method of treating crystal lattice defects.

However, the Joule heating requires application of a higher electrical field to a conductive layer in a shorter period of time to shorten processing time. Accordingly, when an electrical field having an energy content sufficient to reach to about 1100° C. or more is applied to the conductive layer formed of, for example, ITO, the ITO layer may be destroyed due to high hardness. Thus, there is a need for a conductive layer ensuring stability under a condition of high temperature of 1100° C. or more.

### DISCLOSURE OF INVENTION

### Technical Problem

The present invention is directed to a method of fabricating a polycrystalline silicon thin film in which a polycrystalline silicon thin film is formed using high temperature heat generated by Joule heating induced by applying an electrical field to a conductive layer, so as to ensure process stability at high temperature such as 1300° C. or more, reduce processing time, and obtain excellent crystallinity, a polycrystalline silicon thin film fabricated using the method, and a thin film transistor including the polycrystalline silicon thin film.

### Technical Solution

One aspect of the present invention provides a method of fabricating a polycrystalline silicon thin film, including: providing a substrate; forming a metal or metal alloy layer having a melting point of 1300° C. or more on the substrate; forming an insulating layer on the metal or metal alloy layer; forming an amorphous silicon (a-Si) thin film, an amorphous/polycrystalline composite silicon thin film, or a poly-Si thin film on the insulating layer; and applying an electrical filed to the metal or metal alloy layer to induce Joule heating and generate high temperature heat, and crystallizing and annealing the amorphous silicon (a-Si) thin film, the amorphous/polycrystalline composite silicon thin film, or the poly-Si thin film using the high temperature heat.

Another aspect of the present invention provides a method of fabricating a polycrystalline silicon thin film, including: providing a substrate; forming an a-Si thin film, an amorphous/polycrystalline composite silicon thin film, or a poly-Si thin film on the substrate; forming an insulating layer on the a-Si thin film, the amorphous/polycrystalline composite silicon thin film, or the poly-Si thin film; forming a metal or metal alloy layer having a melting point of 1300° C. or more on the substrate; and applying an electrical filed to the metal or metal alloy layer to induce Joule heating and generate high temperature heat, and crystallizing and annealing the a-Si thin film, the amorphous/polycrystalline composite silicon thin film, or the poly-Si thin film using the high temperature heat.

Still another aspect of the present invention provides a polycrystalline silicon thin film crystallized and annealed by the above method.

Yet another aspect of the present invention provides a thin film transistor, including: a substrate; a metal or metal alloy layer having a melting point of 1300° C. or more disposed on the substrate; an insulating layer disposed on the metal or metal alloy layer; a semiconductor layer disposed on the insulating layer, and formed of a poly-Si layer crystallized and annealed due to high temperature heat generated by Joule heating induced by applying an electrical field to the metal or metal alloy layer; a gate insulating layer disposed on the semiconductor layer; a gate electrode disposed on the gate electrode; an interlayer insulating layer disposed on the gate electrode; and source and drain electrodes disposed on the interlayer insulating layer.

### ADVANTAGEOUS EFFECTS

According to the present invention, a method of fabricating a polycrystalline silicon thin film which can ensure process stability at high temperature such as 1300° C. or more, thereby reducing processing time and obtaining a polycrystalline silicon thin film having excellent crystallinity, a polycrystalline silicon thin film fabricated using the same, and a thin film transistor including the polycrystalline silicon thin film are provided.

### BRIEF DESCRIPTION OF THE DRAWINGS

FIG. 1 is a cross-sectional view of a process for crystallizing an amorphous silicon thin film according to a first exemplary embodiment of the present invention.

FIG. 2 is a cross-sectional view of a process of crystallizing an a-Si thin film according to a second exemplary embodiment of the present invention.

FIG. 3 is a cross-sectional view of a process of crystallizing an a-Si thin film and activating a dopant at the same time by applying an electrical field by the same method as described with reference to FIG. 1 according to a third exemplary embodiment of the present invention.

FIG. 4 is a cross-sectional view of a process of crystallizing and thermally oxidizing an a-Si thin film induced by application of an electrical field by the same method as described with reference to FIG. 1 according to a fourth exemplary embodiment of the present invention.

FIG. 5 is a cross-sectional view of a process of re-annealing a poly-Si thin film crystallized by low temperature annealing in advance at high temperature by applying an electrical field by the same method as described with reference to FIG. 1 according to a fifth exemplary embodiment of the present invention.

FIG. 6 is a cross-sectional view of a process of re-annealing a poly-Si thin film crystallized by low temperature annealing in advance and at the same time forming a thermal oxide layer by applying an electrical field by the same method as described with reference to FIG. 1 according to a sixth exemplary embodiment of the present invention.

FIG. 7 is a cross-sectional view of a process of continuously depositing an a-Si thin film and a gate oxide layer in one chamber, and annealing the deposited layers by applying an electrical field by the same method as described with reference to FIG. 1 according to a seventh exemplary embodiment of the present invention.

FIG. 8 is a cross-sectional view of a process of continuously depositing an a-Si thin film and a gate oxide layer, and then re-annealing a poly-Si thin film crystallized in advance through low temperature annealing by applying an electrical field by the same method as described with reference to FIG. 1 according to an eighth exemplary embodiment of the present invention.

FIG. 9 is a photograph of the ITO layer destroyed without standing high temperature over 1100° C. when the electrical field was applied to the ITO layer according to Comparative Example 1.

FIG. 10 is a graph of Raman analysis results for the poly-Si thin film formed by the methods of fabricating a poly-Si thin film according to Examples and Comparative Examples.

FIG. 11 is a cross-sectional view of a thin film transistor including a poly-Si thin film formed by the method of fabricating a poly-Si thin film according to an exemplary embodiment of the present invention.

### MODE FOR THE INVENTION

Hereinafter, the present invention may be modified in various forms, and thus example embodiments will be shown in drawings and described in detail. The scope of the present invention is not limited to the example embodiments disclosed below.

In the present invention, an electrical field is applied to a metal or metal alloy layer having a melting point of 1300° C. or more to induce Joule heating, which refers to heating using heat generated due to a resistance when a current flows through a conductor.

An energy content per unit time applied to the conductive layer, that is, the metal layer having a melting point of 1300° C. or more due to the Joule heating induced by the application of the electrical field can be given by the following equation.

W=V×I

In the equation, W is an energy content per unit time in Joule heating, V is a voltage supplied at both ends of a conductive layer, and I is a current.

It can be noted from the equation that as the voltage (V) and/or the current (I) are/is increased, the energy content per unit time applied to the conductive layer due to the Joule heating is also increased. As a temperature of the conductive layer is increased due to the Joule heating, thermal conduction occurs to a silicon thin film disposed on or under the conductive layer and an underlying substrate (e.g., a glass substrate). Thus, in order to increase the temperature of the silicon thin film due to the thermal conduction to a temperature at which crystallization or dopant activation is possible without heat deflection of the glass substrate, in the present invention, appropriate voltage and current are applied to a sample for a very short period of time. Electrical field application time per cycle may be 1/1,000,000 to 100 seconds, preferably, 1/1,000,000 to 10 seconds, and more preferably, 1/1,000,000 to 1 second. If the applied energy content is sufficient, a crystallization process can be completed with just one shot. However, if the applied energy content is insufficient, a crystallization process may need several shots at regular intervals to complete.

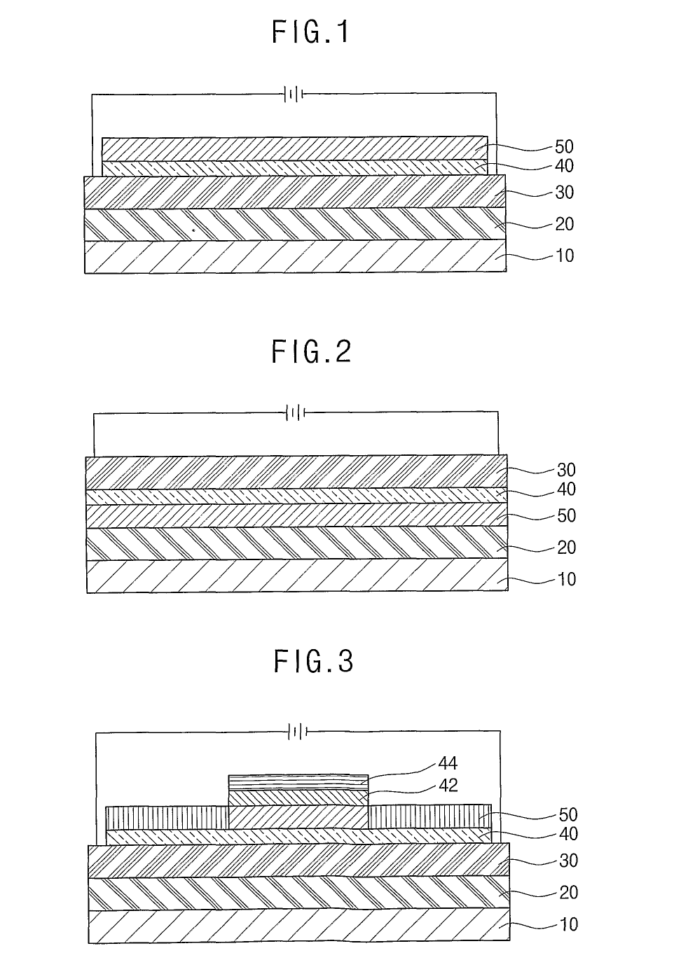

FIG. 1 is a cross-sectional view of a process for crystallizing an amorphous silicon thin film according to a first exemplary embodiment of the present invention.

Referring to FIG. 1, a first insulating layer 20, a metal or metal alloy layer 30 having a melting point of 1300° C. or more, a second insulating layer 40 and an amorphous silicon (a-Si) thin film 50 are sequentially formed on a substrate 10, and then an electrical field is applied to the metal or metal alloy layer 30 to induce Joule heating to generate high temperature heat, thereby crystallizing the a-Si thin film 50.

A material for the substrate 10 is not limited, and thus a transparent substrate may be formed of, for example, glass, quartz or plastic. However, in an economical aspect, glass is preferable for the transparent substrate. According to the recent research trend in the field of flat panel displays, much research on a plastic substrate having excellent impact resistance and processibility has been conducted, and the method of the present invention may also be applied to the plastic substrate.

The first insulating layer 20 is used to prevent elusion of some materials generated in a subsequent process from the substrate 10, for example, an alkali material in the case of a glass substrate. The first insulating layer 20 is generally formed of silicon oxide (SiO₂) or silicon nitride by deposition to preferably have a thickness of 2000 to 5000 Å, but the present invention is not limited thereto. Depending on development of the technology in the future, an a-Si thin film may be directly formed on a substrate without the first insulating layer 20. The method of the present invention can be also applied to such a structure, and it should be understood that this structure is included in the scope of the present invention.

The metal or metal alloy layer 30 having a melting point of 1300° C. or more may be formed of molybdenum (Mo), titanium (Ti), chromium (Cr), and molybdenum-tungsten (MoW) by sputtering or evaporation.

In crystallization by Joule heating, when the temperature of heat is less than 1300° C., the crystallization is not completed by one cycle of the electrical field application, but by several cycles of the electrical field application. In the repeated cycles of the electrical field application, several second intervals are needed between the cycles in order to prevent non-uniformity caused by stored heat. Thus, the overall crystallization takes several minutes.

However, the crystallization using high temperature heat of 1300° C. or more may be completed by one cycle of the electrical field application, and takes only several hundreds of ms. Thus, the crystallization using high temperature heat of 1300° C. or more can significantly reduce total processing time for crystallization. The crystallization induced by one cycle of the electrical field application at high temperature for little processing time can also improve crystallinity.

A conventional ITO layer may be destroyed due to high hardness when high temperature heat of 1100° C. or more is applied, so it cannot ensure stability at high temperature of 1300° C. or more. However, since the metal or metal alloy layer 30 has a melting point of 1300° C. or more, it can ensure stability even if high temperature heat of 1300° C. or more is applied. Thus, when the crystallization is performed using the metal or metal alloy layer 30 and high temperature heat of 1300° C. or more, the processing time can be remarkably reduced.

It is necessary that the metal or metal alloy layer 30 maintains a uniform thickness for uniform Joule heating induced by the electrical field application to be performed in a subsequent process. The metal or metal alloy layer 30 having a melting point of 1300° C. or more may be formed to a thickness of 500 to 3000 Å, but the present invention is not limited thereto.

The second insulating layer 40 functions to prevent contamination of the a-Si thin film 50 to be formed in a subsequent process due to the metal or metal alloy layer 30 having a melting point of 1300° C. or more during annealing and to insulate a TFT device. The second insulating layer 40 may be formed of the same material as the first insulating layer 20.

The a-Si thin film 50 may be formed by, for example, low pressure chemical vapor deposition, high pressure chemical vapor deposition, plasma enhanced chemical vapor deposition (PECVD), sputtering or vacuum evaporation, and preferably, PECVD. The a-Si thin film 50 is preferably formed to a thickness of 300 to 1000 Å, but the present invention is not limited thereto.

Before applying an electrical filed to the metal or metal alloy layer 30 having a melting point of 1300° C. or more, the substrate 10 including the components 10, 20, 30, 40 and 50 may be preheated in an appropriate temperature range. The appropriate temperature range is a temperature range at which the substrate 10 is not damaged throughout the process, and preferably, a temperature range lower than the heat deflection temperature of the substrate 10. The preheating method is not specifically limited, and may be performed by, for example, putting the substrate 10 into a common heat furnace, or applying radiant heat to the substrate 10 using as a lamp.

To apply an electrical field, energy having a power density sufficient to generate high temperature heat of 1300° C. or more by Joule heating is applied to the metal or metal alloy layer 30 having a melting point of 1300° C. or more. The application of the electrical field depends on various factors such as length and thickness of the metal or metal alloy layer 30 having a melting point of 1300° C. or more, so it is difficult to specify. A current applied may be a direct current or an alternating current. Electrical field application time per cycle may be 1/1,000,000 to 100 seconds, preferably, 1/1,000,000 to 10 seconds, and more preferably, 1/1,000,000 to 1 second. The application of the electrical field may be repeated several times regularly or irregularly. Thus, total annealing time may be longer than the electrical field application time, but it is at least shorter than those in the conventional crystallization methods.

FIG. 2 is a cross-sectional view of a process of crystallizing an a-Si thin film according to a second exemplary embodiment of the present invention. The process will be described with reference to the descriptions of the first exemplary embodiment except for particular description below.

Referring to FIG. 2, a first insulating layer 20 is formed on a substrate 10. Unlike the first exemplary embodiment, an a-Si thin film 50 is formed on the first insulating layer 20, and then a second insulating layer 40 and a metal or metal alloy layer 30 having a melting point of 1300° C. or more are sequentially formed on the a-Si thin film 50. Subsequently, an electrical field is applied to the metal or metal alloy layer 30.

FIG. 3 is a cross-sectional view of a process of crystallizing an a-Si thin film and activating a dopant at the same time by applying an electrical field by the same method as described with reference to FIG. 1 according to a third exemplary embodiment of the present invention.

The a-Si thin film 50 is deposited, and a TFT discrete device is patterned by lithography. A gate oxide material is deposited on the patterning device by PECVD, and a gate electrode material is deposited by sputtering. Subsequently, the gate oxide material and the gate electrode material are patterned by lithography and etching to form a gate insulating layer 42 and a gate electrode 44. A source region and a drain region are formed by ion-injecting a dopant into the self-aligned gate structure as described above. Subsequently, an electrical field is applied to the metal or metal alloy layer 30 having a melting point of 1300° C. or more to crystallize the a-Si thin film 50 into a polycrystalline silicon (poly-Si) thin film, and also activate the injected dopant.

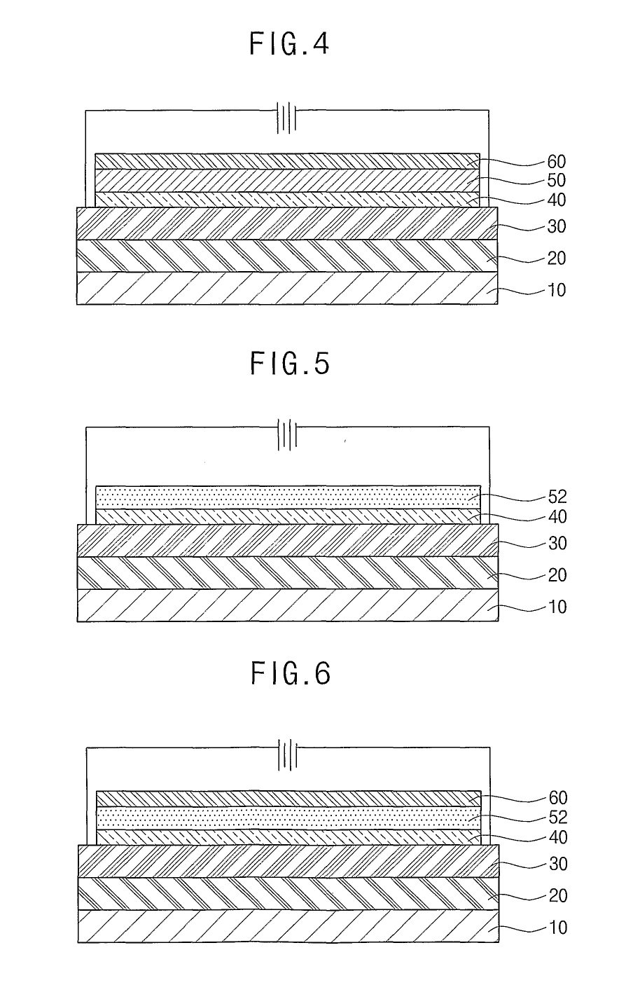

FIG. 4 is a cross-sectional view of a process of crystallizing and thermally oxidizing an a-Si thin film induced by application of an electrical field by the same method as described with reference to FIG. 1 according to a fourth exemplary embodiment of the present invention. During Joule heating, since a temperature of the a-Si thin film 50 is increased to 1300° C. or more, thermal oxidation can also be performed in an oxygen atmosphere. As occasion demands, the thermal oxidation is possible to perform in an ozone or vapor atmosphere or in deionized (DI) water instead of the oxygen atmosphere. In manufacture of a TFT device, due to poor heat resistance of a glass substrate, a PECVD oxide layer is generally deposited instead of a thermal oxide layer having excellent properties. However, according to the present invention, the a-Si thin film 50 may be crystallized into a poly-Si thin film, and at the same time a very thin thermal oxide layer 60 may be formed on the poly-Si thin film due to the electrical field application in an oxygen atmosphere for a short period of time. Afterward, a relatively thick oxide layer (not shown) is deposited on the thin thermal oxide layer 60 by PECVD, and thus the TFT device is completed. Accordingly, an interface characteristic between Si and SiO₂ may be improved.

FIG. 5 is a cross-sectional view of a process of re-annealing a poly-Si thin film crystallized by low temperature annealing in advance at high temperature by applying an electrical field by the same method as described with reference to FIG. 1 according to a fifth exemplary embodiment of the present invention.

A low temperature poly-Si thin film generally has larger grains than a high temperature poly-Si thin film, but the grains contain many crystal lattice defects such as a twinning structure. According to the present invention, although a substrate 10 is formed of glass, it can go through a high temperature process without heat deflection, and thus a large poly-Si thin film which is free from the crystal lattice defects may be fabricated by re-annealing a poly-Si thin film 52 crystallized at low temperature in advance using high temperature heat generated by Joule heating induced by applying an electrical field to a metal or metal alloy layer 30 having a melting point of 1300° C. or more.

FIG. 6 is a cross-sectional view of a process of re-annealing a poly-Si thin film crystallized by low temperature annealing in advance and at the same time forming a thermal oxide layer by applying an electrical field by the same method as described with reference to FIG. 1 according to a sixth exemplary embodiment of the present invention.

Referring to FIG. 6, the process condition is generally the same as a process of fabricating a high-temperature poly-Si thin film using a quartz substrate. Since thermal oxidation is performed at high temperature of 900° C. or more in an oxygen atmosphere, a glass substrate is impossible to use. However, in the present invention, since heating to high temperature takes a very short period of time, even if a substrate 10 is formed of glass, it is possible to form a thermal oxide layer 60 on the substrate 10 without heat deflection of the substrate 10. Nevertheless, the thermal oxidation is performed through a repeated process of heating and cooling when an electrical field is and is not applied, respectively. The thermal oxide layer 60 deposited through the process of the present invention is very thin, and thus a gate oxide layer (not shown) may be formed by an additional PECVD oxide layer process to be performed later. That is, according to the process, an interface characteristic between the gate oxide layer and the poly-Si thin film may be improved, and many crystal lattice defects present in low temperature polycrystalline in the thermal oxidation may be removed.

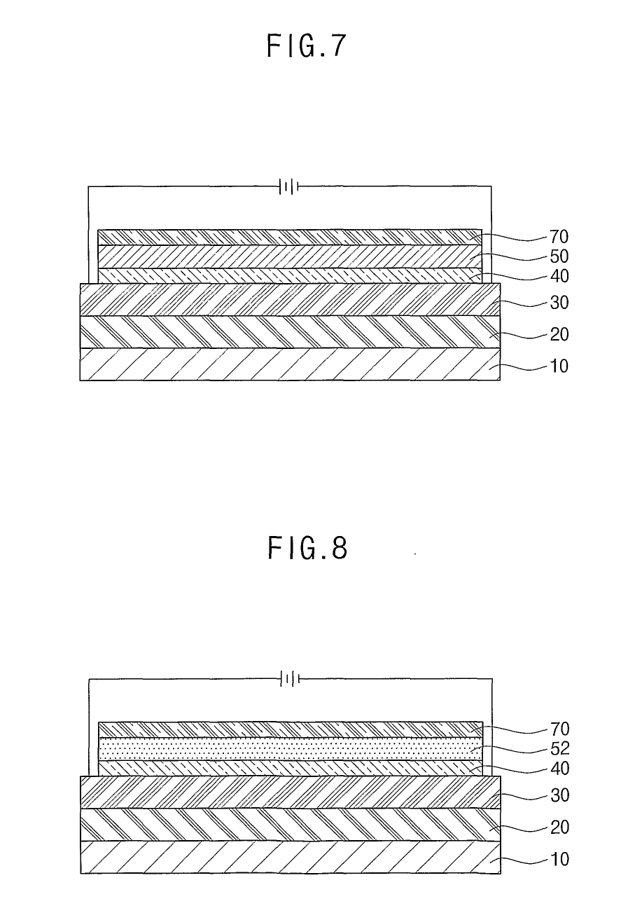

FIG. 7 is a cross-sectional view of a process of continuously depositing an a-Si thin film and a gate oxide layer in one chamber, and annealing the deposited layers by applying an electrical field by the same method as described with reference to FIG. 1 according to a seventh exemplary embodiment of the present invention. An a-Si thin film 50 and a gate oxide layer 70 are continuously deposited in one CVD chamber, and then an electrical field is applied to a metal or metal alloy layer 30 having a melting point of 1300° C. or more by the same method as described with reference to FIG. 1 to crystallize the a-Si thin film 50. Generally, the gate oxide layer formed by continuous deposition has a good interface characteristic, but it cannot be applied to a laser process. Since the method of the present invention does not use laser, it uses the gate oxide layer formed by continuous deposition to achieve an improved device characteristic and a simple process.

FIG. 8 is a cross-sectional view of a process of continuously depositing an a-Si thin film and a gate oxide layer, and then re-annealing a poly-Si thin film crystallized in advance through low temperature annealing by applying an electrical field by the same method as described with reference to FIG. 1 according to an eighth exemplary embodiment of the present invention. An a-Si thin film and a gate oxide layer are continuously deposited, and then the a-Si thin film is crystallized by low temperature annealing. An electrical field is applied to a poly-Si thin film 52 crystallized by the low temperature annealing by the same method as described with reference to FIG. 1 to anneal the poly-Si thin film 52. The method enables both the poly-Si thin film having large grains and fewer defects and the gate oxide layer having the excellent interface characteristic to be obtained.

Hereinafter, the present invention will be described with reference to the following examples and comparative examples, but the scope of the present invention is not limited thereto.

### Example 1

A 3000 Å SiO₂ layer (a first insulating layer) was formed on a glass substrate with a size of 2 cm (L)×2 cm (W)×0.7 mm (H) by PECVD. A 1000 Å molybdenum (Mo) layer was deposited on the first insulating layer by sputtering, and a 1000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the Mo layer was 1.75Ω.

A voltage of 280V/cm was applied to the Mo layer of the sample described above for 300 μs. In the application of the electrical field, an energy content applied to the Mo layer was about 20000 Watt/cm², and instantaneous temperature was increased to 1350° C.

### Example 2

A 3000 Å SiO₂ layer (a first insulating layer) was formed on a glass substrate with a size of 2 cm (L)×2 cm (W)×0.7 mm (H) by PECVD. A 1000 Å titanium (Ti) layer was deposited on the first insulating layer by sputtering, and a 1,000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the Ti layer was 7.5Ω.

A voltage of 500V/cm was applied to the Ti layer of the sample described above for 300 μs. In the application of the electrical field, the energy content applied to the Ti layer was about 19000 Watt/cm², and the instantaneous temperature was increased to 1300° C.

### Comparative Example 1

A 3000 Å SiO₂ layer (a first insulating layer) was formed on a glass substrate with a size of 2 cm (L)×2 cm (W)×0.7 mm (H) by PECVD. A 1000 Å indium tin oxide (ITO) layer was deposited on the first insulating layer by sputtering, and a 1,000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the ITO layer was 30Ω.

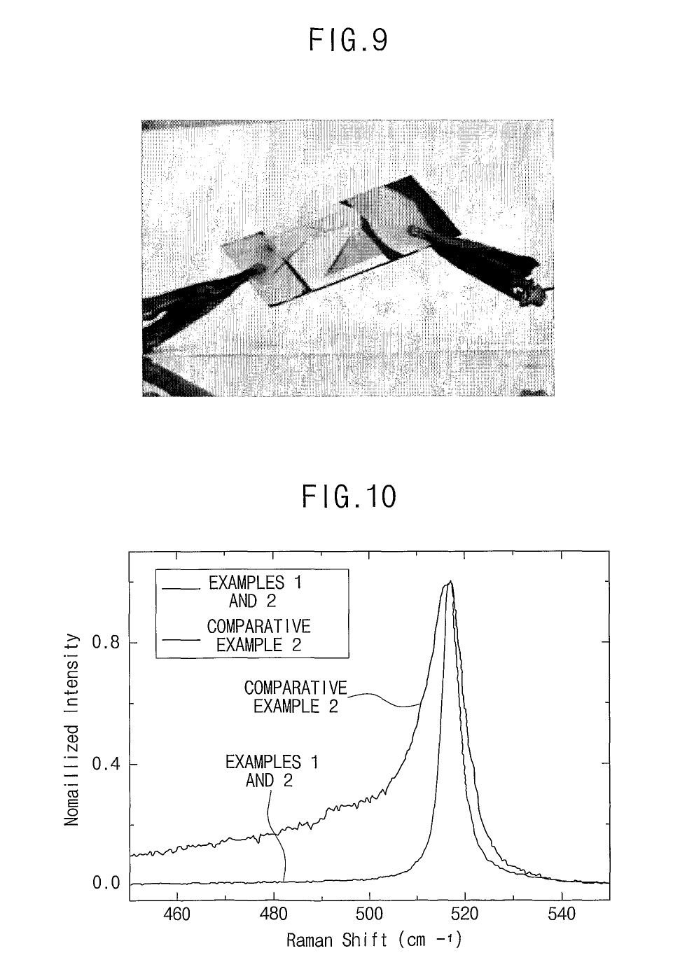

A voltage of 850V/cm was applied to the ITO layer of the sample described above for 300 μs. In the application of the electrical field, the energy content applied to the ITO layer was about 15000 Watt/cm², and the instantaneous temperature was increased to 1150° C. Here, the ITO layer was exploded as shown in FIG. 9.

### Comparative Example 2

A 3000 Å SiO₂ layer (a first insulating layer) was formed on a glass substrate with a size of 2 cm (L)×2 cm (W)×0.7 mm (H) by PECVD. A 1000 Å ITO layer was deposited on the first insulating layer by sputtering, and a 1,000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the ITO layer was 30 Ω.

A voltage of 800V/cm was applied to the ITO layer of the sample described above for 300 μs. In the application of the electrical field, the energy content applied to the ITO layer was about 14500 Watt/cm², and the instantaneous temperature was increased to 1100° C.

### Comparative Example 3

A 3000 Å SiO₂ layer (a first insulating layer) was formed on a glass substrate with a size of 2 cm (L)×2 cm (W)×0.7 mm (H) by PECVD. A 1000 Å ITO layer was deposited on the first insulating layer by sputtering, and a 1,000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the ITO layer was 30Ω.

A voltage of 800V/cm was applied to the ITO layer of the sample described above for 300 μs, this procedure being repeated for 30 cycles at 30 second intervals at room temperature. If the procedure was performed at shorter intervals, non-uniformity could occur due to the stored heat. While the minimum interval at which the non-uniformity did not occur depended on other conditions, it was identified about 10 seconds. As a result, a total electrical field of 9 ms was applied for about 15 seconds. In the application of the electrical field, the energy content applied to the ITO layer was about 14500 Watt/cm², and the instantaneous temperature was increased to 1100° C.

### Comparative Example 4

A 3000 Å SiO₂ layer (a first insulating layer) was formed on a glass substrate with a size of 2 cm (L)×2 cm (W)×0.7 mm (H) by PECVD. A 1000 Å aluminum (Al) layer having a melting point of about 660° C. was deposited on the first insulating layer by sputtering, and a 1,000 Å SiO₂ layer (a second insulating layer) was then deposited by PECVD. A 500 Å a-Si thin film was deposited on the second insulating layer by PECVD, and thus a substrate including the a-Si thin film was completed as shown in FIG. 1. Here, the resistance of the Al layer was 1.5Ω.

A voltage of 150V/cm was applied to the Al layer of the sample described above for 300 μs. In the application of the electrical field, the energy content applied to the Al layer was about 10000 Watt/cm², and the instantaneous temperature was increased to 750° C. Here, an arc occurred.

FIG. 9 is a photograph of the ITO layer destroyed without standing high temperature over 1100° C. when the electrical field was applied to the ITO layer according to Comparative Example 1, and FIG. 10 is a graph of Raman analysis results for the poly-Si thin film formed by the methods of fabricating a poly-Si thin film according to Examples and Comparative Examples.

It can be confirmed from the Raman analysis result for Example 1 that when the instantaneous temperature applied to the metal layer, i.e., the Mo layer reaches to 1350° C. over 1300° C., an a-Si element is not found from the silicon thin film crystallized by just one cycle of the application of the electrical field, which indicates that the silicon thin film is 100% crystallized. It can be also confirmed that the Mo layer is not destroyed after the crystallization is completed.

From the Raman analysis result for Example 2, it can be confirmed that crystallization is 100% completed only one cycle of the application of the electrical field as shown in the result for Example 1 when a high temperature heat of 1300° C. is applied. It can be also confirmed that the Ti layer is not destroyed after the crystallization is completed.

However, in Comparative Example 1, when the instantaneous temperature applied to the ITO layer reaches to 1150° C. higher than 1100° C., as shown in FIG. 9, the ITO layer does not stand the high temperature heat, and thus is destroyed.

Meanwhile, in Comparative Example 2, when the instantaneous temperature applied to the ITO layer is reduced to 1100° C., the ITO layer is not destroyed, but an a-Si element is confirmed from the Raman analysis result for the silicon thin film after the electrical field is applied once as shown in FIG. 10, which indicates that the crystallization is not 100% completed. In Comparative Example 3, it can be confirmed that after the application of the electrical field described in Comparative Example 2 is repeated for 30 cycles, the crystallization can be 100% completed, but it takes 15 minutes.

Compared with Comparative Examples 2 and 3 and Examples, when the temperature applied to the conductive layer is less than 1300° C. like Comparative Examples, the crystallization cannot be completed by the application of 300 μs of electrical field, and the total processing time to complete the crystallization is 15 minutes. However, when the temperature applied to the conductive layer is 1300° C. or more like Examples, the crystallization can be completed by the application of just 300 μs of electrical field, and thus it can be confirmed that the processing time is remarkably reduced.

Meanwhile, in Comparative Example 4, when the Al layer having a melting point of 660° C. lower than 1300° C. is used as a metal layer, it can be confirmed that the Al layer is short-circuited, and therebetween an arc occurs as if it is exploded although heat of just 750° C. is applied to the Al layer.

Thus, when crystallization and annealing are performed by Joule heating using the a metal or metal alloy layer having a melting point of 1300° C. or more, processing time can be significantly reduced, stability at high temperature can be ensured, and a poly-Si thin film having excellent crystallinity can be fabricated.

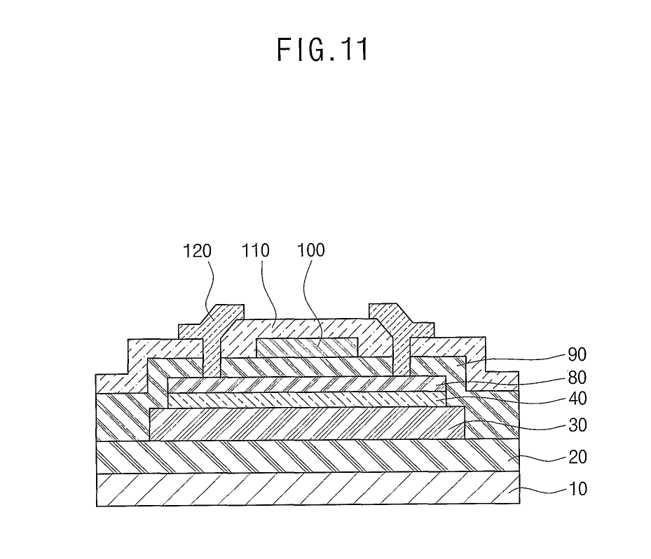

FIG. 11 is a cross-sectional view of a thin film transistor including a poly-Si thin film formed by the method of fabricating a poly-Si thin film according to an exemplary embodiment of the present invention.

Referring to FIG. 11, a semiconductor 80 is formed by patterning a poly-Si thin film formed by the method of fabricating a poly-Si thin film according to the first exemplary embodiment of the present invention. A gate insulating layer 90 is formed on the substrate 10 having the semiconductor layer 80, may be formed of silicon oxide, silicon nitride or a combination thereof, and may include a thermal oxide layer according to the fourth exemplary embodiment of the present invention.

Subsequently, a conductive layer material is deposited on the entire surface of the substrate 10 and patterned, thereby forming a gate electrode 100. An interlayer insulating layer 110 is formed on the entire surface of the substrate 10 having the gate electrode 100. Then, source and drain electrodes 120 electrically connected with source and drain regions of the semiconductor layer 80 are formed on the interlayer insulating layer 110, and thus a thin film transistor is completed.

While the invention has been shown and described with reference to certain example embodiments thereof, it will be understood by those skilled in the art that various changes in form and details may be made therein without departing from the spirit and scope of the invention as defined by the appended claims.

1. A method of fabricating a polycrystalline silicon (poly-Si) thin film, comprising:
providing a substrate;
forming a metal or metal alloy layer having a melting point of 1300° C. or more on the substrate;
forming an insulating layer on the metal or metal alloy layer;
forming an amorphous silicon (a-Si) thin film, an amorphous/polycrystalline composite silicon thin film, or a poly-Si thin film on the insulating layer; and
applying an electrical field to the metal or metal alloy layer to induce Joule heating and generate high temperature heat, and crystallizing and annealing the amorphous silicon (a-Si) thin film, the amorphous/polycrystalline composite silicon thin film, or the poly-Si thin film using the high temperature heat.

2. A method of fabricating a poly-Si thin film, comprising:
providing a substrate;
forming an a-Si thin film, an amorphous/polycrystalline composite silicon thin film, or a poly-Si thin film on the substrate;
forming an insulating layer on the a-Si thin film, the amorphous/polycrystalline composite silicon thin film, or the poly-Si thin film;
forming a metal or metal alloy layer having a melting point of 1300° C. or more on the substrate; and
applying an electrical field to the metal or metal alloy layer to induce Joule heating and generate high temperature heat, and crystallizing and annealing the a-Si thin film, the amorphous/polycrystalline composite silicon thin film, or the poly-Si thin film using the high temperature heat.

3. The method according to claim 1, wherein the metal or metal alloy layer having a melting point of 1300° C. or more is formed of molybdenum (Mo), titanium (Ti), chromium (Cr) or molybdenum-tungsten (MoW).

4. The method according to claim 1, further comprising:
ion-injecting a dopant into the a-Si thin film, the amorphous/polycrystalline composite silicon thin film, or the poly-Si thin film before an electrical field is applied to the metal or metal alloy layer to activate the dopant along with the crystallization and annealing.

5. The method according to claim 1, wherein the electrical field is applied to the metal or metal alloy layer in an oxygen, ozone or vapor atmosphere to form a thermal oxide layer on the a-Si thin film, the amorphous/polycrystalline composite silicon thin film, or the poly-Si thin film along with the crystallization and annealing.

6. The method according to claim 1, wherein the substrate is formed of glass or plastic.

7. The method according to claim 1, further comprising:
forming an insulating layer between the substrate and the metal or metal alloy layer.

8. The method according to claim 2, further comprising:
forming an insulating layer between the substrate and the a-Si thin film, the amorphous/polycrystalline composite silicon thin film, or the poly-Si thin film.

9. The method according to claim 1, further comprising:
preheating the substrate before the electrical field is applied to the metal or metal alloy layer.

10. A poly-Si thin film crystallized and annealed by the method according to claim 1.

11. A thin film transistor, comprising:
a substrate;
a metal or metal alloy layer having a melting point of 1300° C. or more disposed on the substrate;
an insulating layer disposed on the metal or metal alloy layer;
a semiconductor layer disposed on the insulating layer, and formed of a poly-Si layer crystallized and annealed due to high temperature heat generated by Joule heating induced by applying an electrical field to the metal or metal alloy layer;
a gate insulating layer disposed on the semiconductor layer;
a gate electrode disposed on the gate electrode;
an interlayer insulating layer disposed on the gate electrode; and
source and drain electrodes disposed on the interlayer insulating layer.

12. The thin film transistor according to claim 11, wherein the metal or metal alloy layer having a melting point of 1300° C. or more is formed of Mo, Ti, Cr or MoW.

13. The thin film transistor according to claim 11, wherein the gate insulating layer includes a thermal oxide layer formed along with the poly-Si layer crystallized and annealed due to the high temperature heat.

14. The thin film transistor according to claim 11, wherein the substrate is formed of glass or plastic.

15. The method according to claim 2, wherein the metal or metal alloy layer having a melting point of 1300° C. or more is formed of molybdenum (Mo), titanium (Ti), chromium (Cr) or molybdenum-tungsten (MoW).

16. The method according to claim 2, further comprising:
ion-injecting a dopant into the a-Si thin film, the amorphous/polycrystalline composite silicon thin film, or the poly-Si thin film before an electrical field is applied to the metal or metal alloy layer to activate the dopant along with the crystallization and annealing.

17. The method according to claim 2, wherein the substrate is formed of glass or plastic.

18. The method according to claim 2, further comprising:
preheating the substrate before the electrical field is applied to the metal or metal alloy layer.

19. A poly-Si thin film crystallized and annealed by the method according to claim 2.
